(19) United States
(12) Patent Application Publication
(10) Pub. No.: US 2008/0115915 A1
(43) Pub. Date: May 22, 2008

(54) Heat sink

(76) Inventor: Ryan Chen, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/600,024

(22) Filed: Nov. 16, 2006

(51) Int. Cl. H05K 7/20

(52) U.S. Cl. 165/104.33; 361/697; 361/700; 165/80.3; 165/121

(57) ABSTRACT

A heat sink includes a base, at least a heat pipe connecting with the base, and a plurality of fins. The fins form through holes with a slant angle. The heat pipes extend through the through holes. The fins monolithically form an air surface with an inclined guiding angle for heat absorption or dispersion. The fins are assembled on the heat pipes such that the air surface of the fins forms an inclined angle for heat absorption or dispersion. The heat on ambient area around the CPU is effectively eliminated, promoting the whole effect of heat dissipation. The heat pipes are simply assembled, reducing manufacture cost and promoting marketing competence

### BACKGROUND OF THE INVENTION

1. Field of the Invention

The present invention relates to a heat sink, and particularly to a heat sink which has inclined dissipation angle for effectively dissipating heat and simplifying manufacturing.

2. Related Art

With development of electronic technology, IC tends to have high performance, and accordingly speed of CPU promotes quickly. Correspondingly, it is a more and more important issue to control and expel heat. So called 10 degree law means that life of IC would be cut down a half when temperature raises 10 degree. How to keep low temperature of IC is a key design of a heat sink, and decides lifespan of products with IC, especially in the event that speed of CPU promotes rapidly and heat density increases remarkably. In prior art, a fan and a fin are provided on a top of a CPU for dissipating heat. As shown in FIG. 1, a conventional heat sink 90 comprises a base 91, a plurality of heat pipes 92, fins 93 and a fan 94. The base 94 is placed on and contacts a CPU. The fan 94 transfers heat, through the heat pipes 92, to the fins 93 for heat dispersion.

Besides CPU itself, ambient area around CPU is also under high temperature. The heat pipes 92 are perpendicular to the fins 93, and the absorbed or dispersed heat air flows in a single horizontal direction, further referring to FIG. 1A. Correspondingly, heat in ambient area of CPU is not able to be dissipated effectively. So the heat sink 90 can not work efficiently for the overall ambient environment. Furthermore, in order to fixedly assemble the heat pipes 92 and the fins 93 together, at least two soldering points are required between the heat pipes 92 and the fins 93 after the heat pipes 92 extend through the fins 93. Because of this, positioning and assembling of the fins 93 are rather troublesome, prolonging manufacture time and increasing cost, and therefore lowering marketing competence. It is desired to achieve a heat sink which has effective heat dissipation ability and simplifies manufacture process.

### SUMMARY OF THE INVENTION

Accordingly, an object of the present invention is to provide a heat sink effectively cooling CPU and ambient area around CPU.

Another object of the present invention is to provide a heat sink which simplifies structure and manufacture, and therefore reduces manufacture cost.

The heat sink of the present invention comprises a base, at least a heat pipe connecting with the base, and a plurality of fins. The fins form through holes with a slant angle. The heat pipe extends through the through holes. The fins monolithically form an air surface with an inclined guiding angle for heat absorption or dispersion.

Projecting edges are stamped from the fins for bordering the through holes. One soldering point connects the heat pipe and the fins.

The heat pipe is bent to form an arcuate shape. The heat pipe defines inward areas which respectively receive fans.

### BRIEF DESCRIPTION OF THE DRAWINGS

FIG. 1 is a perspective view of a conventional heat sink.

FIG. 1A exemplarily shows assembly of a heat pipe and fins of the conventional heat sink in FIG. 1.

FIG. 2 is a perspective view of a heat sink according to the present invention.

FIG. 3 is a partially cross-sectional view of the heat sink of FIG. 2.

FIG. 3A and 3B are partially cross-sectional views of fins of the heat sink.

FIG. 4 exemplarily shows assembly of a heat pipe and fins of the heat sink of FIG. 2.

FIG. 5 exemplarily shows a heat pipe being soldered to fins of the heat sink of FIG. 2.

FIG. 6 is a partially cross-sectional view of the heat sink according to a second embodiment of the present invention.

FIG. 7 exemplarily shows an arcuate shape of the heat sink in FIG. 6.

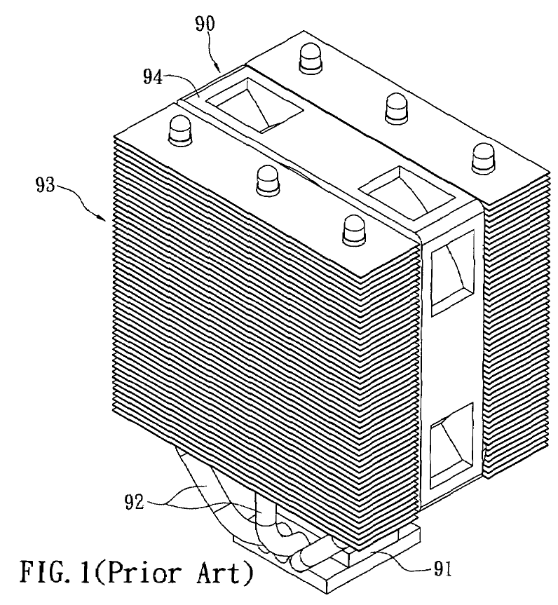

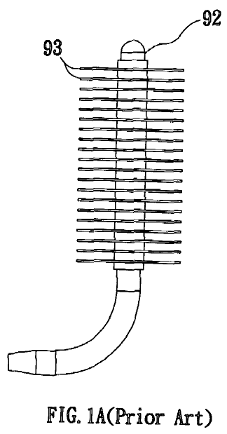

### DESCRIPTION OF THE PREFERRED EMBODIMENTS

With reference to FIGS. 2 through 4, a heat sink in accordance with the present invention comprises a base 10, a plurality of heat pipes 20, a plurality of fins 30 and a fan 40. The base 10 is placed on a CPU (not shown) for absorbing heat generated by the CPU. Ends of the heat pipes 20 connect with the base 10. In other embodiments, another ends of the heat pipes 20 rewind and connect with the base 10.

The heat pipes 20 extend through and position the fins 30. The fins 30 form an inclined air surface 31 and a touching surface 32. The air surface 31 forms an inclined guiding angle α for heat absorption or dispersion. The fan 40 is provided on and joints the touching surface 32 for absorbing/dispersing heat from/toward the fins 30. The heat pipes 20 conduct and radiate the heat.

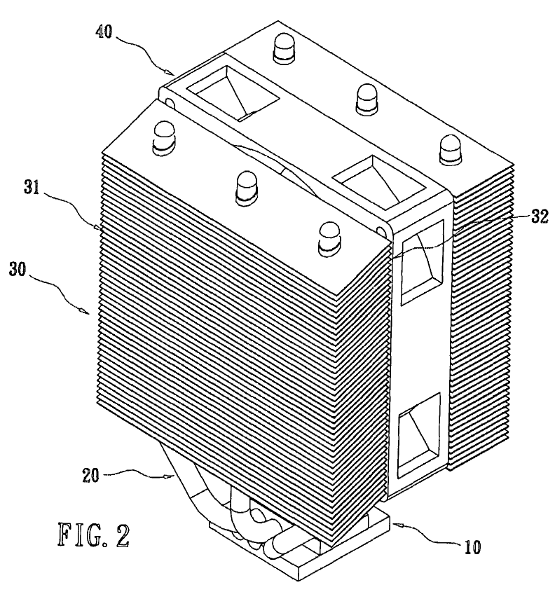

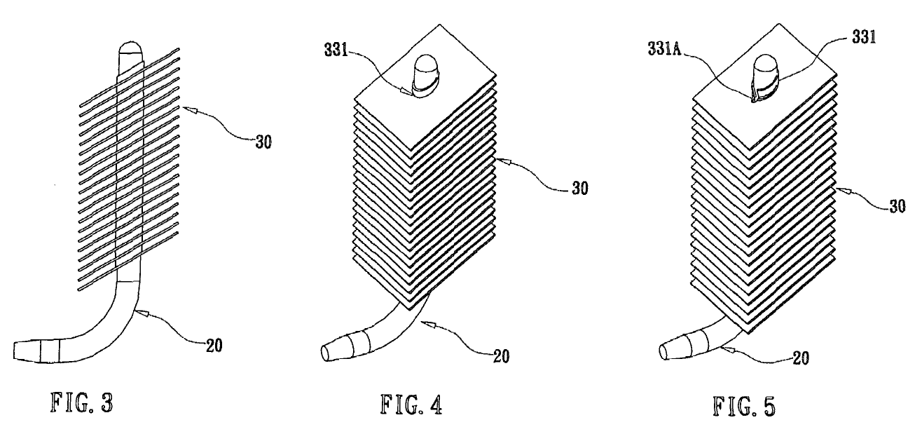

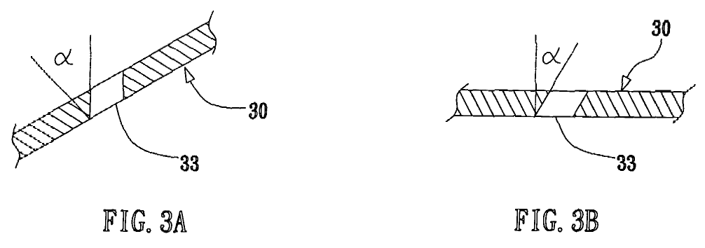

Referring to FIGS. 3A and 3B, the fins 30 form through holes 33 with a slant angle α, namely, the through holes 33 forms a slant angle α with regards to a longitudinal direction of the fins 30. In the case that the heat pipes 20 extend through the through holes 33 of the fins 30, the fins 30 are oriented inclinedly relative to the heat pipes 20 with an inclined angle α therebetween, which differs from the single horizontal direction in prior art. Although in prior art, the heat pipes 20 may be put inclinedly and form an inclined angle relative to the fins, a touching surface for jointing a fan is, correspondingly, put inclindedly, making manufacturing more complicated.

The inclined guiding angle α of the air surface 31 corresponds to ambient air around the CPU. When the fan 40 starts to work, heat in ambient area of the CPU is absorbed or dispersed due to the inclined guiding angle α of the air surface 31, thereby reducing heat and promoting heat dispersion ability.

Moreover, the through holes 33 with the slant angle α enlarge jointing area of the heat pipes 20 with the fins 30, thereby enhancing connection therebetween. Also referring to FIGS. 4 and 5, projecting edges 331 are stamped from the fins 30 and border the through holes 33. The projecting edges 331 further enlarge jointing area of the heat pipes 20 with the fins 30. Thus, jointing area between the heat pipes 20 and the fins 30 are enlarged by the through holes 33 and the projecting edges 331. Only one soldering point 331A connects the heat pipes 20 and the fins 30, which is sufficient to assemble the heat pipes 20 and the fins 30 reliably. This reduces soldering operation, thereby simplifying manufacture and assembly and decreasing cost.

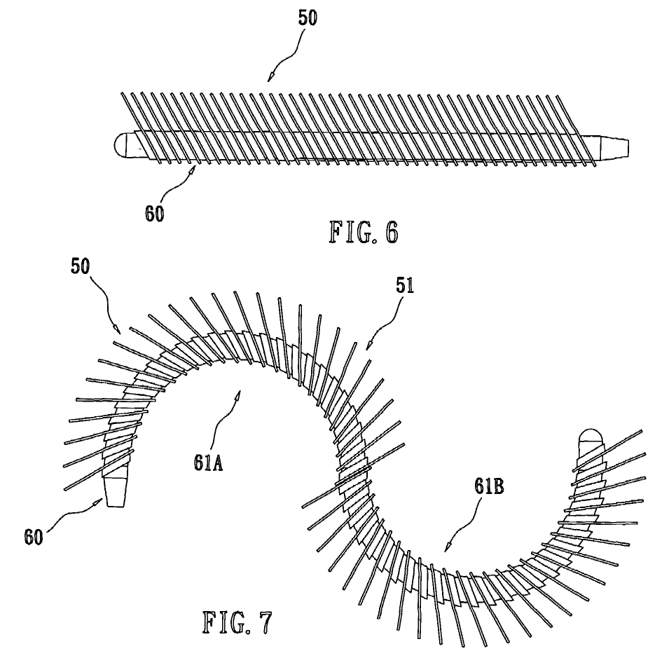

FIGS. 6 and 7 show a heat sink according to a second embodiment of the present invention. Fins 50 of the heat sink are positioned on the heat pipes 60 with an inclined angle α (identical to the inclined angle α). Then the heat pipes 60 are bent to form arcuate shape, for example S shape. The arcuate shape of heat pipes 60 defines inward areas 61A, 61B in which a fan (not shown) is placed. Dissipation areas 51 at outward sides of the fins 50 provide even and effective radiation space.

When the fins are assembled on the heat pipes, the air surface of the fins forms an inclined guiding angle for heat absorption or dispersion owing to the through holes with a slant angle. The heat in ambient area around the CPU is effectively absorbed or dispersed, promoting the whole effect of heat dissipation. The heat pipes are simply assembled, reducing manufacture cost and promoting marketing competence.

It is understood that the invention may be embodied in other forms without departing from the spirit thereof. Thus, the present examples and embodiments are to be considered in all respects as illustrative and not restrictive, and the invention is not to be limited to the details given herein.

1. A heat sink comprising:
a base;
at least a heat pipe connecting with the base; and
a plurality of fins forming through holes with a slant angle, the heat pipe extending through the through holes, the fins monolithically forming an air surface with an inclined guiding angle for heat absorption and dispersion.

2. The heat sink as claimed in claim 1, wherein the heat pipe rewinds and connects with the base.

3. The heat sink as claimed in claim 1, wherein the fins form a touching surface, and a fan is provided on the touching surface.

4. The heat sink as claimed in claim 1, wherein projecting edges are stamped from the fins for bordering the through holes.

5. The heat sink as claimed in claim 1, wherein one soldering point connects the heat pipe and the fins.

6. The heat sink as claimed in claim 1, wherein the heat pipe is bent to form an arcuate shape.

7. The heat sink as claimed in claim 6, wherein a fan is placed in an inward area of the arcuate shape of the heat pipe.

8. A heat sink comprising at least a heat pipe and a plurality of fins, the fins forming through holes with a slant angle, the heat pipe extending through the through holes, the fins being oriented inclinedly relative to the heat pipes with an inclined angle therebetween.

9. The heat sink as claimed in claim 8, wherein projecting edges are stamped from the fins for bordering the through holes.

10. The heat sink as claimed in claim 1, wherein one soldering point connects the heat pipe and the fins.
